(19) United States
(12) Patent Application Publication
(10) Pub. No.: US 2007/0251677 A1
(43) Pub. Date: Nov. 1, 2007

(54) HEAT DISSIPATION APPARATUS WITH GUILDING PLATES FOR GUIDING AIRFLOW FLOWING THROUGH A FIN ASSEMBLY

(75) Inventors: CHING-BAI HWANG, TU-CHENG (TW); JIN-GONG MENG, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., TU CHENG (TW)

(21) Appl. No.: 11/308,727

(22) Filed: Apr. 26, 2006

(51) Int. Cl. H05K 7/20

(52) U.S. Cl. 165/122; 165/80.3; 165/185; 361/697; 257/722

(57) ABSTRACT

A heat dissipation apparatus (10) for dissipating heat from a heat generating electronic component includes a fin assembly (14) thermally connecting with the heat-generating electronic component to absorb heat therefrom, and a heat-dissipating fan (12) for providing an airflow to take heat away from the fin assembly. The heat-dissipating fan includes a bottom housing (124), a top cover (125) mounted on the bottom housing to form a space therebetween, and a rotor with a plurality of blades (122) accommodated in the space. The top cover extends a plurality of guiding plates (127) therefrom for guiding the airflow from the blades toward the fin assembly.

### FIELD OF THE INVENTION

The present invention relates generally to a heat dissipation apparatus, and more particularly to a heat dissipation apparatus for dissipating heat generated by electronic components, wherein the apparatus has guiding plates for guiding an airflow to flow more smoothly and evenly through a fin assembly.

### DESCRIPTION OF RELATED ART

Following the increase in computer processing power that has been seen in recent years, greater emphasis is now being laid on increasing the efficiency and effectiveness of heat dissipation devices. Referring to FIG. 4, a conventional heat dissipation apparatus 20 includes a heat-dissipating fan 22 and a fin assembly 24 disposed at an air outlet 221 of the heat-dissipating fan 22. The fin assembly 24 includes a plurality of fins 242 which thermally connect with a heat generating electronic component (not shown) to absorb heat therefrom. The heat-dissipating fan 22 includes a casing 222, a stator (not shown) mounted in the casing 222, and a rotor 223 rotatably disposed around the stator. When the heat-dissipating fan 22 is activated, the rotor 223 rotates along a counterclockwise direction around the stator to drive an airflow to flow through the fin assembly 24 to take away heat therefrom.

In operation of the heat dissipation apparatus 20, the casing 222 guides the airflow to move toward an upper side 246 of the air outlet 221 of the heat-dissipating fan 22. A portion of the airflow leaves the heat-dissipating fan 22 at the upper side 246 of the air outlet 221 with another portion flowing toward a bottom side 244 of the fin assembly 24 from the upper side 246 thereof. A flow direction of the airflow flowing toward the upper side 246 of the fin assembly 24 is substantially parallel to the fins 242 thereof, while the airflow flowing toward the bottom side 244 of the fin assembly 24 forms an acute angle with each fin 242 of the bottom side 244 of the fin assembly 24. The airflow flowing toward the bottom side 244 of the fin assembly 24 may be deflected by the fins 242 thereof due to the acute angles formed therebetween. This deflection of the airflow may cause a loss in kinetic energy of the airflow. Thus speed of the airflow flowing toward the bottom side 244 of the fin assembly 24 may be reduced. The heat dissipation efficiency of the heat dissipation apparatus 20 will thereby be further reduced. Accordingly, it can be seen that the heat dissipation efficiency of the heat dissipation apparatus 20 has room for improvement.

### SUMMARY OF INVENTION

The present invention relates to a heat dissipation apparatus for dissipating heat from a heat-generating electronic component. According to a preferred embodiment of the present invention, the heat dissipation apparatus includes a fin assembly thermally connecting with the heat-generating electronic component to absorb heat therefrom, and a heat-dissipating fan for providing an airflow flowing through the fin assembly to take heat away therefrom. The heat-dissipating fan includes a bottom housing, a top cover mounted on the bottom housing to form a space therebetween, and a motor with a plurality of blades accommodated in the space. The top cover extends a plurality of guiding plates therefrom for guiding the airflow from the blades toward the fin assembly.

Other advantages and novel features of the present invention will become more apparent from the following detailed description of preferred embodiment when taken in conjunction with the accompanying drawings, in which:

### BRIEF DESCRIPTION OF DRAWINGS

FIG. 1 is an assembled view of a heat dissipation apparatus according to a preferred embodiment of the present invention;

FIG. 2 is an exploded, isometric view of the heat dissipation apparatus of FIG. 1, with the heat dissipation apparatus being arranged in an inverted manner;

FIG. 3 is a bottom view of the heat dissipation apparatus of FIG. 1 with a bottom housing thereof removed; and

FIG. 4 is a top view of a conventional heat dissipation apparatus with some parts thereof removed.

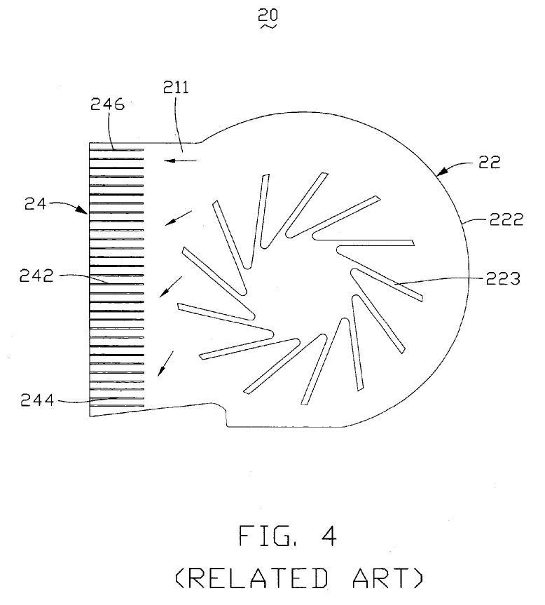

### DETAILED DESCRIPTION

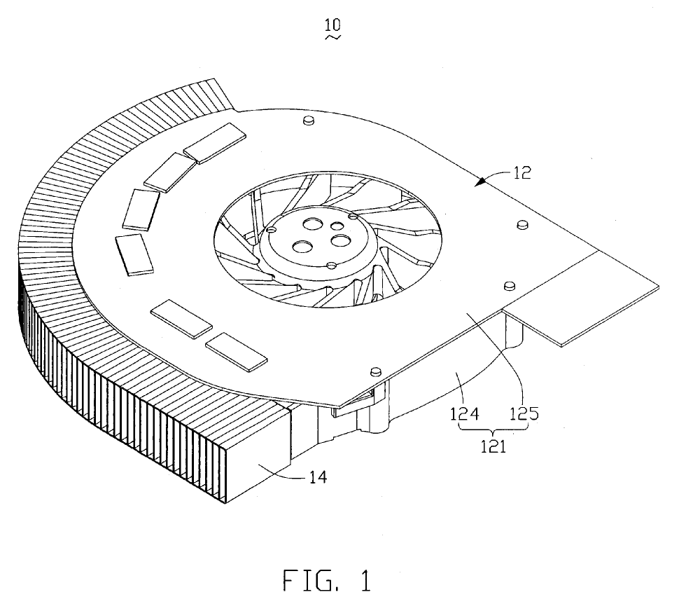

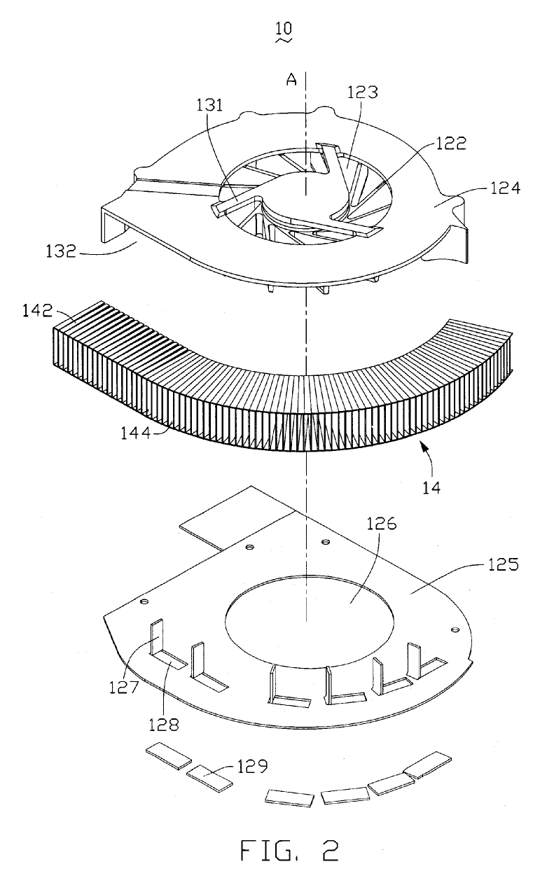

Referring to FIGS. 1 to 3, a heat dissipation apparatus 10 according to a preferred embodiment of the present invention is shown. The heat dissipation apparatus 10 includes a heat-dissipating fan 12 and an arc-shaped fin assembly 14.

The fin assembly 14 thermally connects with a heat-generating electronic component (not shown) to absorb heat therefrom. The fin assembly 14 includes a plurality of stacked fins 142. A plurality of air passages 144 is formed between two adjacent fins 142.

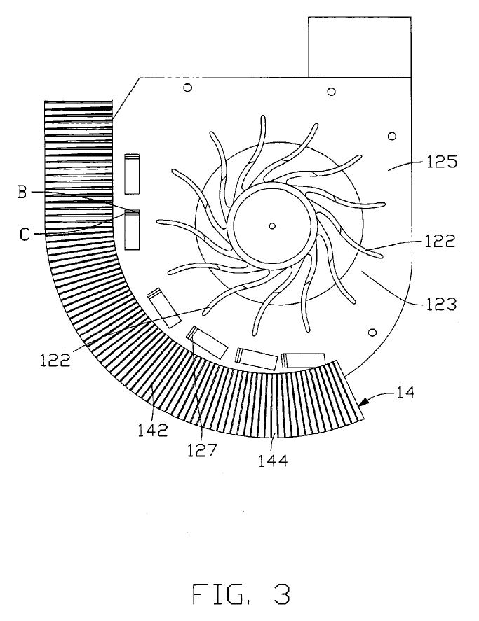

The heat-dissipating fan 12 is a centrifugal blower for providing an airflow with a high air pressure. The heat-dissipating fan 12 includes a casing 121, a stator (not shown) mounted in the casing 121, and a rotor including a plurality of blades 122 rotatably disposed around the stator. Referring to FIG. 3, an air channel 123 is formed between free ends of the blades 122 and an inner surface of the casing 121. A width of the air channel 123 is gradually increased along a clockwise direction as viewed from FIG. 3.

The casing 121 includes a bottom housing 124 and a top cover 125 mounted on the bottom housing 124. The top cover 125 is a plate made of metallic materials such as aluminum, steel, and copper or any appropriate alloys thereof. The bottom housing 124 is made of a plastic material, and formed by injection molding.

The top cover 125 defines a through hole therein function as an air inlet 126 of the heat-dissipating fan 12. A plurality of guiding plates 127 are formed by stamping/pressing perpendicularly to and downwardly from the top cover 125 toward the bottom housing 124, thereby forming a plurality of gaps 128 on the top cover 125. A plurality of covering plates 129 are disposed on the gaps 128 of the top cover 125, so as to prevent the air flow in the casing 121 of the heat-dissipating fan 12 from escaping the heat-dissipating fan 12 via the gaps 128.

The bottom housing 124 extends a supporting portion 131 from a middle portion thereof so as to support the stator. A sidewall of the bottom housing 124 defines an arc-shaped opening therein which functions as an air outlet 132 for the heat-dissipating fan 12. The arc-shaped fin assembly 14 is mated with the air outlet 132 of the heat-dissipating fan 12. The guiding plates 127 are located between the blades 122 and the fin assembly 14, and distributed around a rotational axis A of the rotor. Referring particularly to FIG. 3, the surface of a front end B of the guiding plate 127 adjacent to the blade 122 aligns with the free end of an adjacent blade 122 as the adjacent blade 122 rotates to a point where it is closest to the front end B. A rear end C of each guiding plate 127 adjacent to the fin assembly 14 aligns with the body of the adjacent fin 142. In other words, an extension direction of the front end B of each guiding plate 127 substantially parallels that of the free end of the adjacent blade 122 at that point, and an extension direction of the rear end C of each guiding plate 127 substantially parallels to that of the adjacent fin 142. Thus, the airflow flowing from the blades 122 is distributed evenly between the air passages 144 of the fin assembly 14 by the guiding plates 127. As the fan 12 is activated, the blades 122 of the rotor rotate along a clockwise direction (as viewed in FIG. 3) around the stator (not shown) propelling the air in the casing 121 of the fan 12 to leave the fan 12 via the guiding plates 127. The guiding plates 127 distribute evenly between the fins 142 whilst also aligning the airflow so as to be substantially parallel to the extending directions of the fins 142 adjacent to each of the guiding plates 127. Finally, the airflow reaches the fin assembly 14 to be distributed into many smaller airflows via the fins 142 of the fin assembly 14. A flow direction of each of the smaller airflows parallels the extension direction of the corresponding fin 142.

In the present invention, the guiding plates 127 distribute the airflow from the blades 122 evenly over the fins 142, and change the flow direction of each part of the airflow to the direction so as to be substantially parallel to the extending directions of the fins 142 adjacent to the guiding plate 127. The flow direction of the airflow reaching different parts of the fin assembly 14 is substantially parallel to the extending directions of the adjacent fins 142. So the airflow arriving at the fin assembly 14 can not be deflected by the fins 142 of the fin assembly 14. The kinetic energy loss from the airflow is thus prevented and the heat dissipation efficiency of the heat dissipation apparatus 10 is thereby increased.

In the present invention, the guiding plates 127 are stamped/pressed from the top cover 125 toward the bottom housing 124. If the guiding plates 127 were formed at the bottom housing 124, they should have been integrally formed on the bottom housing 124 by injection molding. The present invention omits the manufacture a mold for the formation of the guiding plates 127. This simplifies both the design of the mold of the bottom housing 124 and also the manufacture of the heat-dissipating fan 12. Thus, the cost of the heat-dissipating fan 12 is reduced. Moreover, through such manufacturing the guiding plates 127 may reduce the noise produced during the operation of the heat-dissipating fan 12. This noise reduction is produced because using stamping/pressing to form the guiding plates 127 allows a thinner shape than that produced by injection molding. The thinner shaped guiding plates 127 have lower airflow resistance, thereby making the airflow flow evenly through the spaces formed between adjacent guiding plates 127. Therefore, the noise produced during operation of the heat-dissipating fan 12 is reduced.

In the present invention, the air outlet 132 of the heat-dissipating fan 12 and the fin assembly 14 each have an arc-shaped configuration. Alternatively, the heat-dissipating fan may have a rectangular or circular shaped air outlet, and the fin assembly may accordingly have a correspondingly rectangular or circular shaped configuration.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation apparatus configured for dissipating heat from a heat-generating electronic component comprising:
a fin assembly configured for thermally connecting with the heat-generating electronic component to absorb heat therefrom; and
a heat-dissipating fan for providing an airflow flowing through the fin assembly to take heat away therefrom, the heat-dissipating fan comprising a bottom housing, a top cover mounted on the bottom housing to form a space therebetween, and a motor with a plurality of blades accommodated in the space, the top cover extending a plurality of guiding plates therefrom for guiding the airflow from the blades toward the fin assembly.

2. The heat dissipation apparatus as described in claim 1, wherein an end of the guiding plate adjacent to a corresponding blade aligns with a free end of the corresponding blade as that blade rotates to a point where it is closest to the end.

3. The heat dissipation apparatus as described in claim 1, wherein an end of each guiding plate adjacent to the fin assembly aligns with an adjacent fin of the fin assembly.

4. The heat dissipation apparatus as described in claim 1, wherein the guiding plates are stamped/pressed from the top cover toward the bottom housing.

5. The heat dissipation apparatus as described in claim 1, wherein the top cover is a plate made of metallic material.

6. The heat dissipation apparatus as described in claim 1, wherein the bottom housing is formed by injection molding.

7. The heat dissipation apparatus as described in claim 1, wherein the bottom housing defines an opening therein which functions as an air outlet of the heat dissipating fan, the fin assembly is mounted at the air outlet of the heat dissipating fan to sandwich the guiding plates between the blades of the heat dissipating fan and the fin assembly.

8. The heat dissipation apparatus as described in claim 7, wherein a configuration of the air outlet of the heat-dissipating fan is arc-shaped, and a configuration of the fin assembly is correspondingly arc-shaped.

9. The heat dissipation apparatus as described in claim 1, wherein the heat-dissipating fan is a centrifugal blower.

10. A heat dissipation apparatus comprising:
a fin assembly comprising a plurality of fins; and
a heat-dissipating fan comprising a housing, a plate covered to the housing, and a rotor comprising a plurality of blades rotatably disposed in the housing, the plate comprising a plurality of guiding plates extending therefrom and disposed between the blades and the fin assembly, each of the guiding plate comprising an end adjacent to the fin assembly which parallels to an extension direction of a corresponding adjacent fin.

11. The heat dissipation apparatus as described in claim 10, wherein the guiding plate comprises an opposite end adjacent to the blade which parallels an extension direction of a free end of a corresponding adjacent blade.

12. The heat dissipation apparatus as described in claim 10, wherein the guiding plates are distributed around a rotational axis of the rotor.

13. The heat dissipation apparatus as described in claim 10, wherein the guiding plates are stamped/pressed from the plate toward the housing.

14. The heat dissipation apparatus as described in claim 13, wherein a plurality of gaps are formed on the top cover by stamping/pressing of the guiding plates, a plurality of covering plates are disposed on the gaps for preventing airflow generated by the heat-dissipating fan from escaping via the gaps.

15. The heat dissipation apparatus as described in claim 10, wherein the plate is made of metallic material.

16. The heat dissipation apparatus as described in claim 10, wherein a configuration of the fin assembly is arc-shaped, and a configuration of the air outlet of the heat-dissipating fan is arc-shaped.

17. A heat dissipation apparatus comprising:
a casing having an inlet and an arc-shaped outlet, the inlet being defined in a top of the casing while the outlet is defined in a side of the casing;
a fan rotatably received in the casing for generating an airflow from the inlet through the outlet;
an arc-shape fin assembly conformingly mounted on the outlet of the casing; and
a plurality of guiding members being located in the casing between the fan and the fin assembly for guiding the airflow, the guiding members being shaped with portions thereof being aligned with some of fins of the fin assembly thereby to guide the airflow to smoothly flow through the fin assembly.

18. The heat dissipation apparatus as described in claim 17, wherein the casing has an upper cover and a lower base, the inlet is defined in the upper cover and the guiding members are formed on the upper cover by stamping the upper cover, the guiding members extending from the cover towards the base.

19. The heat dissipation apparatus as described in claim 18, wherein holes defined in the cover by forming the guiding members are covered by covering plates.

20. The heat dissipation apparatus as described in claim 18, wherein the guiding members are distributed around a rotational axis of the fan.
